(19) United States
(12) Patent Application Publication
(10) Pub. No.: US 2012/0199476 A1
(43) Pub. Date: Aug. 9, 2012

(54) Production of Nanoparticles

(75) Inventor: Lars Allers, Oxfordshire (GB)

(73) Assignee: MANTIS DEPOSITION LIMITED, Oxfordshire (GB)

(21) Appl. No.: 13/424,870

(22) Filed: Mar. 20, 2012

(30) Foreign Application Priority Data
Sep. 21, 2009 (GB) 0916510.0

(51) Int. Cl. C23C 14/35; B82Y 99/00; B82Y 40/00

(52) U.S. Cl. 204/298.12; 977/891; 977/773

(57) ABSTRACT

An apparatus for the production of nanoparticles comprises a chamber, a magnetron located within the chamber and comprising a cylindrical target having at least an outer face of the material to be deposited and a hollow interior, a source of magnetic flux within the hollow interior arranged to present magnetic poles in a direction that is radially outward with respect to the cylindrical target, and a drive arrangement for imparting a relative motion in an axial direction to the target and the source of magnetic flux, the chamber having at least one aperture and being located within a volume of relatively lower gas pressure compared to the interior of the chamber. The chamber is preferably substantially cylindrical, and is ideally substantially co-axial with the target so as to offer a symmetrical arrangement.

### FIELD OF THE INVENTION

The present invention relates to the production of nanoparticles.

### BACKGROUND ART

One established method for the deposition of materials is sputter deposition. According to this method, a target composed of the material to be deposited is placed over a magnetron in a chamber containing a low pressure inert gas such as Argon. A plasma is then created immediately above the target, and high energy collisions with gas ions from the plasma cause the target to (in effect) undergo forced evaporation into the low pressure chamber. The evaporated material is not in thermodynamic equilibrium and will condense onto nearby surfaces, creating a thin film coating. Alternatively, the evaporated atoms can be caused to travel through appropriate conditions to create nanoparticles.

Sputter deposition has not however met with wide commercial acceptance, and (other than in specialist contexts) is primarily a laboratory tool. This is mainly due to the slow rate of deposition that is achieved, and the difficulty involved in scaling the process up which means that batch sizes are relatively small. These two factors combine to militate against the use of sputtering on an industrial scale.

Sputtering is however useful in the production of a surface film of nanoparticles, by allowing atoms in a stream partially to condense during their flight towards a substrate. This can be encouraged by allowing a slightly elevated gaseous pressure to subsist in the flight path.

To encourage the nanoparticles to settle on the surface of the substrate, it can be brought to an elevated electrical potential. Depending on the method by which the nanoparticle stream is produced, some of the nanoparticles will have become negatively charged by acquiring electrons. Sputter methods are suitable since they involve the production of a plasma at the surface of the material source, so the nanoparticles will (to an extent) inherit charge and be attracted to a positively charged substrate.

### SUMMARY OF THE INVENTION

The present invention seeks to allow sputtering to move towards a more commercial scale, by adopting a geometry that is more susceptible to operation on an increased scale, and which is more susceptible to the large-scale production of nanoparticles.

In its first aspect, therefore, the present invention provides an apparatus for the production of nanoparticles, comprising a chamber, a magnetron located within the chamber and comprising a cylindrical target having at least an outer face of the material to be deposited and a hollow interior, a source of magnetic flux within the hollow interior arranged to present magnetic poles in a direction that is radially outward with respect to the cylindrical target, and a drive arrangement for imparting a relative motion in an axial direction to the target and the source of magnetic flux, the chamber having at least one aperture and being located within a volume of relatively lower gas pressure compared to the interior of the chamber.

The chamber is preferably substantially cylindrical, and is ideally substantially co-axial with the target so as to offer a symmetrical arrangement.

The motion of the target means that the erosion of its active surface is spread over a wider area, rather than being concentrated in local regions. This allows more efficient use of the target material, which is especially useful where more valuable materials are required. Nanoparticles are often used for the catalytic properties they exhibit as a result of their large surface area, so materials such as Pt or Pd are often deposited meaning that efficient usage of the target material has a strong effect on the cost of the process.

The motion of the target is preferably a reciprocating one, to allow a single discrete target to be used. Generally, it is easier if the source of magnetic flux remains stationary and the target moves, but other arrangements are possible.

The source of magnetic flux can be a plurality of permanent magnets or an electromagnet. Further, the cylindrical target can contain at least one axially-extending conduit for a coolant fluid.

The source of magnetic flux preferably presents a north magnetic pole in a radially outward direction at a plurality of first locations that are circumferentially spaced and axially co-located, and presents a magnetic south pole in a radially outward direction at a plurality of second locations that are circumferentially spaced and axially co-located and which are axially spaced from the first locations. This creates a magnetic field at the target surface that alternates along an axial direction, in which a plasma for sputter deposition can be created. We further prefer that the like poles extend around the complete circumference of the target, thus forming circumferential bands around the target of alternating north and south magnetic poles. We also prefer that the poles alternate many times along the axial length of the target; these arrangements contribute to a greater efficiency of the target.

Where we refer to “magnets” in this application, we intend by this term to mean any source of magnetic flux. This obviously includes permanent magnets, of which there are a wide variety of types, but also includes electromagnets.

### BRIEF DESCRIPTION OF THE DRAWINGS

An embodiment of the present invention will now be described by way of example, with reference to the accompanying figures in which;

FIG. 1 shows a schematic view of a magnetron and target according to the present invention;

FIG. 2 shows a radial section through the magnetron of FIG. 1;

FIG. 3 shows an in position within a chamber, in axial section; and

FIG. 4 shows a subsequent instantaneous view of the magnetron of FIG. 3.

### DETAILED DESCRIPTION OF THE EMBODIMENTS

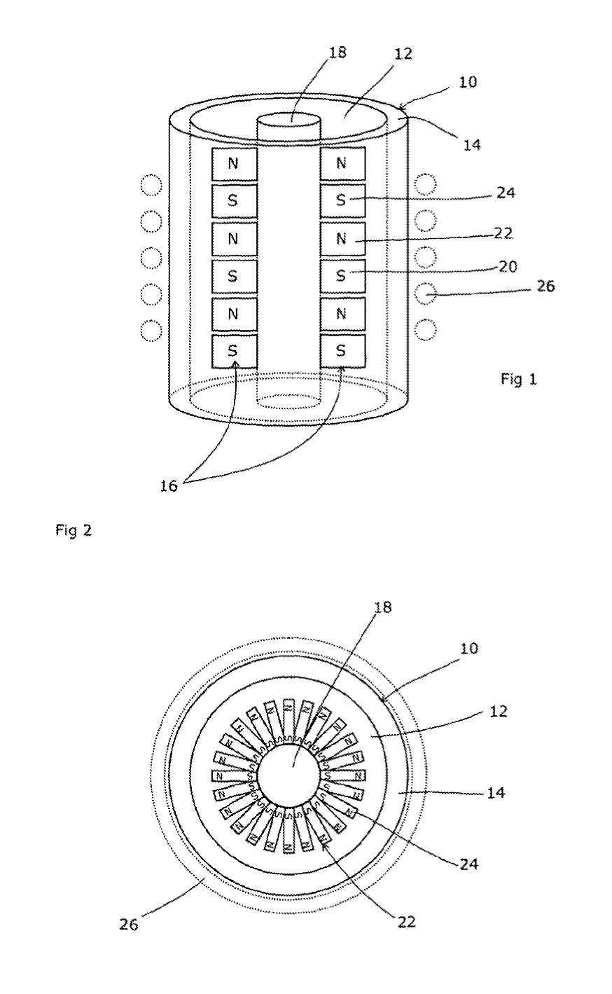

FIGS. 1 and 2 show a magnetron suitable for use in the present invention. A target 10 is formed in the shape of a hollow cylinder, with a concentric interior space 12 that leaves an annular section of material 14 to form the target. As illustrated, the target is a solid annulus of the material to be deposited, but depending on the choice of material it may alternatively be in the form of an inert or substantially inert former carrying an external layer or coating of the material to be deposited.

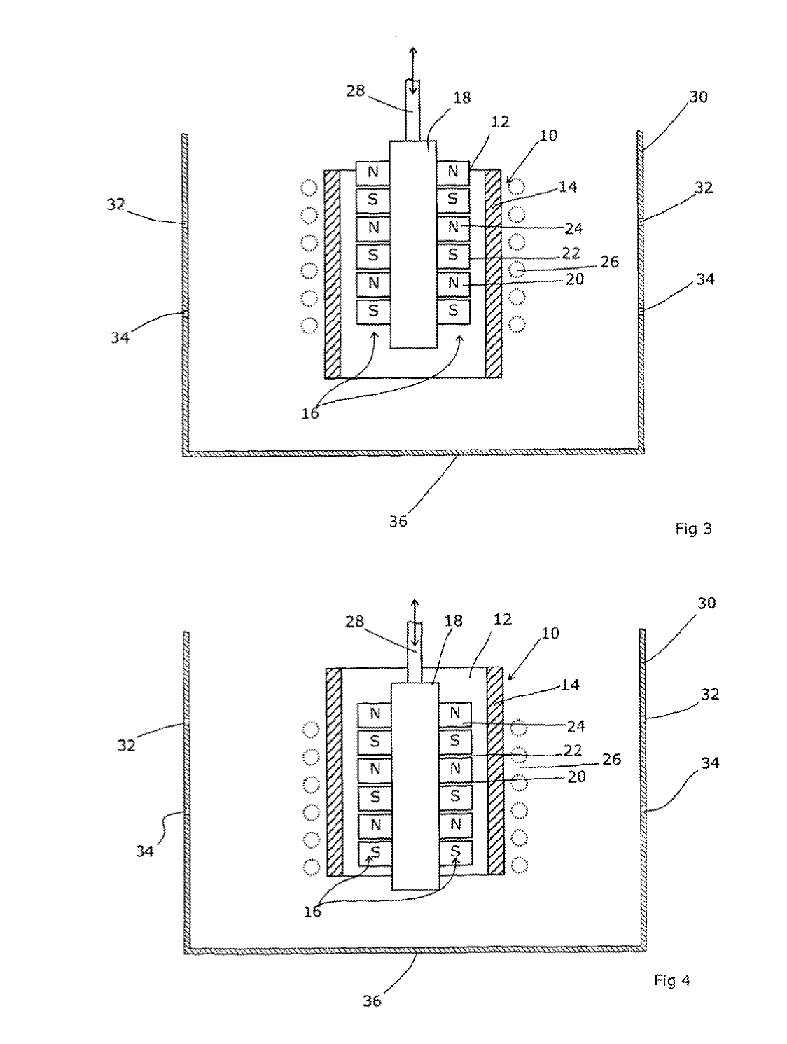

Within the interior space 12, there is an array of permanent magnets 16 to create the necessary magnetic field patterns for sputtering. These are mounted on a centrally-located support 18 and are arranged in a series of axially-spaced rings 20, 22, 24. Each ring presents an alternating magnetic pole in a radial outward direction; FIG. 2 shows a single ring 22 of permanent magnets 24, from which is can be seen that the ring consists of a large number of bar magnets all arranged in a radial direction with their South pole (in this case) located proximate the central support 18. This leaves their North poles directed radially outwards. In the rings above 24 and below 20 the ring 22 illustrated in FIG. 3, the orientations of the magnets 24 are reversed, so that a South pole is directed radially outwardly. Thus, along the axial direction the magnetic pole reverses repeatedly, thereby allowing the production of a localised plasma 26 at locations between each ring 20, 22, 24.

Other arrangements of magnets would of course work, producing differently shaped plasmas.

Such a magnetron can be made in essentially any length desired, by duplicating the arrangement shown in FIGS. 1 to 3 the required number of times. Items to be coated can be arrayed around the interior walls of a chamber surrounding the magnetron, and the cylindrically symmetric nature of the magnetron will mean that all will be coated. This can be contrasted with known magnetrons which emit a directional flow of material; items to be coated therefore need to be placed within a relatively limited space. The omnidirectional nature of the magnetron allows for a much more efficient usage of the chamber that contains it.

Sputter processes do however consume the target in the vicinity of the plasma 26. This leads to a local thinning of the target, which means that the target needs to be replaced when that thinning becomes unacceptable. Areas of the target that are not adjacent a plasma will still then be substantially at their original thickness, but the target as a whole will be largely unusable. Replacement of the entire target is of course very wasteful of material, and while used targets can be recycled to create new targets, this has a significant energy footprint and therefore has an associated expense.

The magnetron layout shown in FIGS. 1 and 2 is however especially suitable to a resolution of this problem. By mounting the support 18 and/or the target 10 in an axially moveable manner, the erosion of the target can be made more even. Ideally, one or both will be made to move in a reciprocating manner with an amplitude that is similar to or slightly smaller than the spacing between the axially-spaced rings 20, 22, 24, or a multiple thereof.

The movement could be a sinusoidal form, such as would be provided by a simple crank arrangement driving the support 18 and (in turn) driven by a rotary motor. Alternatively, a sawtooth time/displacement profile could be imposed, for example via a linear motor or a servo. Other or more complex profiles could of course be provided, such as via a stepper motor controlled by a computing means provided with feedback as to the actual or calculated consumption rate of the target and arranged to move the target in response thereto.

FIG. 3 shows such a magnetron arrangement, in this case set up for the production of nanoparticles. A target 10 is fitted around a support 18 carrying the necessary magnetron arrangement, as in FIGS. 1 and 2. This is mounted on a support arm 28 which is connected to a reciprocating drive (not shown). As mentioned above, this can be one of a number of possible sources of reciprocating motion but is (in this case) a crank arrangement. Thus, rotation of the crank to which the arm 28 is connected causes the support 18 to move back and forth within the (fixed) target 10 according to a sinusoidal movement. The amplitude of the crank is, in this example, set to be the same as the spacing between successive poles of the magnets 20, 22 and 24, and therefore during each motion the plasma regions 26 sweep across contiguous sections of the outerface of the target 10.

The result of this is that, of the region of the target 10 that is within reach of at least one plasma region 26, the entirety of the outer face of the target 10 is swept. Erosion of the target 10 is therefore uniform along its outer face and the usage of the target 10 is at its most efficient.

As mentioned previously, the target 10 can be in the form of an inner shell of an inert or substantially inert material onto which is coated the material to be deposited. This could be extended further by way of a former having an external coating or upper external layer of the target material 10 extending over the region swept by the plasmas 26.

FIG. 4 shows the apparatus at a later instant, with the support 18 at the lowest point of its reciprocating motion as opposed to the highest point shown in FIG. 3. The movement of the support 18 need not be especially fast, but should be sufficiently swift as to prevent the development of significant surface irregularities in the target. Such irregularities might harm the stability of the plasma 26.

Both FIGS. 3 and 4 show the sputter source within a chamber 30. This has a plurality of arrays 32, 34 of apertures extending from the interior of the chamber 30 to the exterior of the chamber, each array consisting of a series of small circular apertures, extending in a line around a complete diameter of the cylindrical chamber 30. End cap 36 seals one end of the chamber 30; the other end (not visible in FIGS. 3 and 4) is also closed, other than to allow ingress of the necessary drives and/or conduits.

The region outside the chamber 30 is held at a very low gas pressure, close to vacuum. The region within the chamber 30, including the sputter source, is however held at a slightly relatively elevated gas pressure, although still distinctly below atmospheric pressure. The result of this is that there is a steady outflow of gas through the apertures 32, 34, causing a flow of gas within the chamber 30 that is radially outwardly away from the sputter source towards the apertures 32, 34. Gas within the chamber 30 is replenished via a suitable conduit (not shown) in order to maintain the chosen pressure, and the escaping gas is collected via a vacuum pump in order to maintain the necessary low pressure outside the chamber 30.

The result of this is that atoms evaporated from the sputter target 10 are caused to lose energy by collision with gas within the chamber 30, and cool so as to coalesce and form nanoparticles. These nanoparticles are caught up in the gas flow and exit the chamber 30 via the apertures 32, 34 after which they can be collected by known means. The relative gas pressures within and without the chamber 30 therefore dictate the dwell time and the cooling rate within the chamber 30 and accordingly offer control over the size profile of the nanoparticles that result.

In this way, the arrangement can produce significant numbers of nanoparticles by the more efficient use of the sputter target 10 and the significant production rates that can be achieved using a specially symmetric apparatus.

It will of course be understood that many variations may be made to the above-described embodiment without departing from the scope of the present invention.

1. Apparatus for the production of nanoparticles, comprising:
a chamber;
a magnetron, located within the chamber, and comprising a cylindrical target having at least an outer face of the material to be deposited and a hollow interior, a source of magnetic flux within the hollow interior arranged to present magnetic poles in a direction that is radially outward with respect to the cylindrical target, and a drive arrangement for imparting a relative motion in an axial direction to the target and the source of magnetic flux;
the chamber having at least one aperture and being located within a volume of relatively lower gas pressure compared to the interior of the chamber.

2. Apparatus for the production of nanoparticles according to claim 1 in which the chamber is substantially cylindrical.

3. Apparatus for the production of nanoparticles according to claim 2 in which the chamber is substantially co-axial with the target.

4. Apparatus for the production of nanoparticles according to claim 1 in which the motion is a reciprocating motion.

5. Apparatus for the production of nanoparticles according to claim 1 in which the source of magnetic flux remains stationary and the target moves.

6. Apparatus for the production of nanoparticles according to claim 1 in which the source of magnetic flux is a plurality of permanent magnets.

7. Apparatus for the production of nanoparticles according to claim 1 in which the source of magnetic flux is an electromagnet.

8. Apparatus for the production of nanoparticles according to claim 1 in which the source of magnetic flux presents alternating north and south magnetic poles in circumferential bands around the target.

9. Apparatus for the production of nanoparticles according to claim 1 in which the source of magnetic flux presents a north magnetic pole in a radially outward direction at a plurality of first locations that are circumferentially spaced and axially co-located, and presents a magnetic south pole in a radially outward direction at a plurality of second locations that are circumferentially spaced and axially co-located and which are axially spaced from the first locations.

10. Apparatus for the production of nanoparticles according to claim 1 in which the target contains at least one axially-extending conduit for a coolant fluid.

11. Apparatus for the production of nanoparticles substantially as herein disclosed with reference to and/or as illustrated in the accompanying figures.
